(19) United States
(12) Patent Application Publication
(10) Pub. No.: US 2025/0079384 A1
(43) Pub. Date: Mar. 6, 2025

(54) COMPLIANT ELECTRICAL INTERCONNECT ARRAYS USING COPPER NANO-WIRES (CUNWS) IN POLYMERIC PRE-FORM ATTACHMENT LAYER

(71) Applicants: BOARD OF TRUSTEES OF THE UNIVERSITY OF ARKANSAS, Little Rock, AR (US); BOARD OF TRUSTEES OF THE LELAND STANFORD JUNIOR UNIVERSITY, Palo Alto, CA (US)

(72) Inventors: David Huitink, Prairie Grove, AR (US); Kenneth Goodson, Stanford, CA (US); Mehdi Asheghi, Oakland, CA (US); Katherine Jiang, Stanford, CA (US)

(73) Assignees: BOARD OF TRUSTEES OF THE UNIVERSITY OF ARKANSAS, Little Rock, AR (US); BOARD OF TRUSTEES OF THE LELAND STANFORD JUNIOR UNIVERSITY, Palo Alto, CA (US)

(21) Appl. No.: 18/823,341

(22) Filed: Sep. 3, 2024

Related U.S. Application Data
(60) Provisional application No. 63/535,948, filed on Aug. 31, 2023.

(51) Int. Cl. H01L 23/00; C25D 1/00; C25D 1/04; C25D 5/56

(52) U.S. Cl. CPC H01L 24/29; C25D 1/006; H01L 24/27; H01L 24/83; H01L 2224/271; H01L 2224/29111; H01L 2224/29147; H01L 2224/29291; H01L 2224/29347; H01L 2224/83191

(57) ABSTRACT

Embodiments of the present disclosure pertain to a material that includes: (1) a first copper-based layer; (2) a copper nanowire layer above the first copper-based layer, which generally includes a plurality of copper nanowires embedded with a polymer; and (3) a second copper-based layer positioned above the copper nanowire layer such that the copper nanowire layer is sandwiched between the first copper-based layer and the second copper-based layer. Additional embodiments of the present disclosure pertain to methods of forming a material of the present disclosure.

### CROSS-REFERENCE TO RELATED APPLICATIONS

This application claims priority to U.S. Provisional Patent Application No. 63/535,948, filed on Aug. 31, 2023. The entirety of the aforementioned application is incorporated herein by reference.

### STATEMENT REGARDING FEDERALLY SPONSORED RESEARCH

This invention was made with government support under Grant No. 1449548, awarded by the National Science Foundation. The government has certain rights in the invention.

### BACKGROUND

A need exists for improved systems and methods of mitigating the effect of thermal expansion mismatch on various electronic materials. Numerous embodiments of the present disclosure aim to address the aforementioned need.

### SUMMARY

In some embodiments, the present disclosure pertains to a material that includes: (1) a first copper-based layer; (2) a copper nanowire layer above the first copper-based layer, which generally includes a plurality of copper nanowires embedded with a polymer; and (3) a second copper-based layer positioned above the copper nanowire layer such that the copper nanowire layer is sandwiched between the first copper-based layer and the second copper-based layer. In some embodiments, the materials of the present disclosure also include: (4) a first substrate beneath the first copper-based layer; and (5) a second substrate above the second copper-based layer.

Additional embodiments of the present disclosure pertain to methods of forming a material of the present disclosure. In some embodiments, such methods include: (1) growing a copper nanowire layer on a first copper-based layer; (2) embedding the copper nanowire layer with a polymer; and (3) positioning a second copper-based layer above the copper nanowire layer such that the copper nanowire layer becomes sandwiched between the first copper-based layer and the second copper-based layer. In some embodiments, the methods of the present disclosure also include a step of: (4) positioning a first substrate beneath the first copper-based layer; and (5) positioning a second substrate above the second copper-based layer.

### BRIEF DESCRIPTION OF THE DRAWINGS

A better understanding of the present invention can be obtained when the following detailed description is considered in conjunction with the following drawings, in which:

FIG. 1 provides an illustration of a material of the present disclosure.

FIGS. 2A-2D provide additional illustrations of the materials of present disclosure. FIG. 2A provides scanning electron microscopy (SEM) images of copper nanowires (CuNWs) with diameters of about 450 nm and volume fractions between 20 and 25%. FIGS. 2B and 2C provide schematics of an electrical and thermal compliant CuNWs interface material (EIMs & TIMs). The CuNWs are sandwiched between (Cu—Sn) bonding layers at the top and bottom to produce stable bonds (at 300° C.) between the CuNWs EIMs & TIMs, and adjacent substrates from the top and bottom sides before (FIG. 2B) and after (FIG. 2C) reflow subjected to high temperature and pressure to complete the bonding. FIG. 2D shows that the CuNWs IEMs & TIMs can be prepatterned to any shape and form, grid array or any other configurations. Applicant's initial target is to demonstrate 0.5-1 mm by 0.5-1 mm to form a grid array.

FIGS. 3A-3B provide additional illustrations of the materials of present disclosure. FIG. 3A shows an SEM image and a schematic of EIMs & TIMs interconnects (24 μm) sandwiched between (Cu—Sn) bonding layers at the top and bottom. The CuNWs EIMs & TIMs can be prepatterned to any shape and form, grid array or any other configurations. FIG. 3B provides an SEM image of a polycarbonate track-etched (PTCE) membrane.

FIGS. 4A-4L provide schematics, illustrations and photographs related to the fabrication of the materials of the present disclosure.

### DETAILED DESCRIPTION

It is to be understood that both the foregoing general description and the following detailed description are illustrative and explanatory, and are not restrictive of the subject matter, as claimed. In this application, the use of the singular includes the plural, the word “a” or “an” means “at least one”, and the use of “or” means “and/or”, unless specifically stated otherwise. Furthermore, the use of the term “including”, as well as other forms, such as “includes” and “included”, is not limiting. Also, terms such as “element” or “component” encompass both elements or components comprising one unit and elements or components that include more than one unit unless specifically stated otherwise.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that one or more of the incorporated literature and similar materials defines a term in a manner that contradicts the definition of that term in this application, this application controls.

To curb the effect of thermal expansion mismatch, solder attachment based compliant interconnect structures between dies and substrates have been proposed using photolithography and additive manufacturing approaches. Electronics packaging development is greatly dependent on the magnitude of interconnect and on-chip stress that ultimately limits the reliability of electronic components.

Thermomechanical strains occur because of the coefficient of thermal expansion mismatch from different conjoined materials being assembled to manufacture a device. In flip chip devices, microscale solder joints are used to increase I/O density while reducing package parasitic inductance. However, the solder accommodates these coefficient of thermal expansion (CTE) induced strains with their plasticity, accumulating damage that leads to creep and fatigue generated failures.

Alternatively, in high temperature power packages, compatible attachment materials like transient liquid phase (TLP) attachment, sintered Ag, or hi-T solders produce more rigid, fatigue cracking-susceptible connections, especially at low temperatures. Consequently, this lack of plasticity may have reduced lifetimes compared to traditional solders due to CTE induced stresses, despite allowing higher operating temperatures.

To curb the effect of thermal expansion mismatch, studies have been done in integrating compliant structures between dies, solder balls, and substrates. Initial studies have enabled the design and manufacturing of these structures using a photolithography approach, which involves an increased number of fabrication steps depending on the complexity of the structures.

Additional studies utilized additive manufacturing that reduces the number of fabrication steps required to obtain compliant geometries, while also providing a platform for unique compliant structures. Such studies conducted structural finite element thermal cycling simulations between-40 to 125° C. to show about a 115% increase in the solder joint fatigue life.

Additionally, fabricated test structures created directly on a PCB were experimentally characterized for compliance using a micro-indenter tester, showing a mechanical compliance range of 265 to 656 μm/N for selected design parameters to be integrated into a test vehicle. However, the integration of large compliant “springlike” features comes at a great cost of interconnect density, in addition to increased thermal isolation of the die from the substrate. These structures increase the effective conduction path from the die, since they use suspended serpentine architectures to reduce the interfacial stiffness between package layers.

As such, a need exists for improved systems and methods of mitigating the effect of thermal expansion mismatch on various electronic materials. Numerous embodiments of the present disclosure aim to address the aforementioned need.

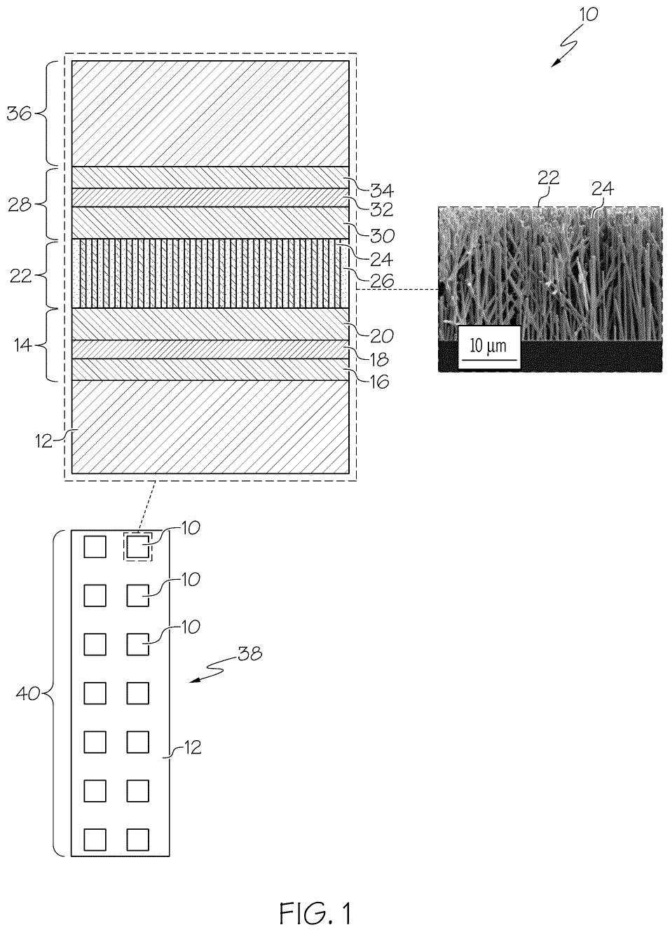

In some embodiments, the present disclosure pertains to a material. An example of a material of the present disclosure is illustrated in FIG. 1 as material 10. Material 10 includes a first copper-based layer 14; a copper nanowire layer 22 above the first copper-based layer 14; and a second copper-based layer 28 positioned above the copper nanowire layer 22 such that the copper nanowire layer 22 is sandwiched between the first copper-based layer 14 and the second copper-based layer 28. Copper nanowire layer 22 generally includes a plurality of copper nanowires 24 embedded with a polymer 26.

In some embodiments, material 10 also includes a first substrate 12 beneath the first copper-based layer 14. In some embodiments, material 10 also includes a second substrate 36 above the second copper-based layer 28.

The materials of the present disclosure can have numerous structures and variations. For instance, in some embodiments further illustrated in FIG. 1, first copper-based layer 14 includes a first copper layer 16, a second copper layer 20, and a Sn layer 18 sandwiched between the first copper layer 16 and the second copper layer 20. In some embodiments, the second copper layer 20 interfaces with the copper nanowire layer 22. In some embodiments, the Sn layer 18 includes Cu—Sn bonds between the Sn layer 18, the first copper layer 16 and the second copper layer 20.

In some embodiments further illustrated in FIG. 1, the second copper-based layer 28 includes a first copper layer 30, a second copper layer 34, and a Sn layer 32 sandwiched between the first copper layer 30 and the second copper layer 34. In some embodiments, the first copper layer 30 interfaces with the copper nanowire layer 22. In some embodiments, the Sn layer 32 includes Cu—Sn bonds between the Sn layer 32, the first copper layer 30 and the second copper layer 34.

Additional embodiments of the present disclosure pertain to methods of forming a material of the present disclosure. In some embodiments, such methods include: growing a copper nanowire layer on a first copper-based layer; embedding the copper nanowire layer with a polymer; and positioning a second copper-based layer above the copper nanowire layer such that the copper nanowire layer becomes sandwiched between the first copper-based layer and the second copper-based layer.

In some embodiments, the methods of the present disclosure also include a step of positioning a first substrate beneath the first copper-based layer. In some embodiments, the methods of the present disclosure also include a step of positioning a second substrate above the second copper-based layer.

As set forth in more detail herein, the materials and methods of the present disclosure can have numerous embodiments. Additionally, the materials of the present disclosure can be incorporated into various electronic devices.

### Cooper Nanowires

The materials of the present disclosure can include various copper nanowires. Additionally, the methods of the present disclosure may be used to grow various copper nanowires. For instance, in some embodiments, the copper nanowires are in the form of an array of vertically aligned nanowires. In some embodiments, the carbon nanowires are in the form of bundles.

The carbon nanowires of the present disclosure can include various diameters. For instance, in some embodiments, each of the carbon nanowires of the present disclosure include diameters ranging from about 50 nm to about 750 nm. In some embodiments, each of the carbon nanowires of the present disclosure include diameters ranging from about 50 nm to about 450 nm. In some, the carbon nanowire arrays include a total diameter ranging from about 50 μm to about 100 μm. In some, the carbon nanowire arrays include a total diameter of more than about 100 μm. In some, the carbon nanowire arrays include a total diameter of more than about 1 mm.

The carbon nanowires of the present disclosure can include various heights. For instance, in some embodiments, the carbon nanowires of the present disclosure include heights ranging from about 1 μm to about 500 μm. In some, the carbon nanowire arrays of the present disclosure include heights ranging from about 20 μm to about 50 μm. In some, the carbon nanowire arrays of the present disclosure include heights of at least about 20 μm. In some, the carbon nanowire arrays of the present disclosure include heights of at least about 30 μm.

Various methods may be utilized to grow the copper nanowires of the present disclosure. For instance, in some embodiments, the copper nanowires are produced through a semi-subtractive approach. In some embodiments, the semi-subtractive approach leverages both use of a subtractive template for producing nano features through electroplating technology, followed by using layer-based deposition and lithographic patterning.

In some embodiments, the growth of copper nanowires is confined to isolated regions by selective growth methodologies, such as masking. In some embodiments, the growth of copper nanowires is confined to isolated regions by selectively etching areas where wires are not desired. In some embodiments, the grown copper nanowires can be patterned to any shape or form.

### Polymers

The copper nanowires of the present disclosure may be embedded with various polymers. Additionally, the methods of the present disclosure may embed copper nanowires with various polymers. For instance, in some embodiments, the polymer is operable to provide support to the carbon nanowires while also being thermally stable at temperatures applicable to electronics operation (e.g., temperatures of around 200° C.). In some embodiments, polymers associated with copper nanowire arrays provide a compressible interposer that allows for pressure assisted bonding with high temperature that reduces stress on device interconnects, thereby controlling the compressive deflection during pressure application.

In some embodiments, the polymer includes an elastomeric polymer. In some embodiments, the polymer includes, without limitation, polydimethylsiloxane (PDMS), polybutadiene, polystyrene, co-polymers thereof, or combinations thereof. In some embodiments, the polymer includes polydimethylsiloxane (PDMS). In some embodiments, the plurality of copper nanowires are infiltrated with the polymer.

### Material Forms

The materials of the present disclosure can be in various forms. For instance, in some embodiments, the material is a thermal interface material. In some embodiments, the material is an electrically and thermally conductive material. In some embodiments, the material is in the form of a tape.

In some embodiments illustrated in FIG. 1, material 10 may be a component of an electronic device 38. In some embodiments, material 10 is positioned on electronic device 38 in the form of an array 40. In some embodiments, the array 40 includes a plurality of materials 10. In some embodiments, the plurality of materials 10 are electrically isolated from one another.

In some embodiments, the methods of the present disclosure also include a step of incorporating the materials of the present disclosure as a component of an electronic device. In some embodiments, the incorporating includes positioning the material on the electronic device in the form of an array.

The materials of the present disclosure may be components of various electronic devices. For instance, in some embodiments, the electronic device includes, without limitation, processors, memory devices, graphics, power devices, micro-electromechanical systems (MEMS), sensors, flexible electronics, wearable electronic devices, or combinations thereof.

### Applications and Advantages

The materials of the present disclosure provide numerous advantages. For instance, in some embodiments, the materials of the present disclosure can be patterned in electrically isolated arrays. In some embodiments, the materials of the present disclosure can match solder joint pitch and retain small interconnect lengths (e.g., for improved inductance and conductivity) while reducing the effective strain on the solder connection to the device.

As such, in some embodiments, the materials of the present disclosure can reduce CTE mismatch stresses on more than 15% of device connections for enhanced lifetime. In some embodiments, the materials of the present disclosure can exhibit comparable or better thermal and electrical properties to bulk solder joints. In some embodiments, materials of the present disclosure enable high temperature solders to accommodate extreme temperature delta environments.

In some embodiments, the materials of the present disclosure provide significant advantages over solder ball grid arrays. For instance, in some embodiments, the materials of the present disclosure provide higher electrical conductivity, enhanced mechanical compliance, and more versatile patterning capabilities when compared to Sn solder balls. In particular, since copper nanowires have superior electrical properties and fatigue resilience when compared to solder ball grid arrays, the nanowire structures enable mechanical compliance to accommodate thermomechanical strains in the copper nanowire tape, which consequently reduces stress on the solder connections, thereby improving lifetime.

Moreover, the materials of the present disclosure can be prepatterned to any shape and form, grid array or any other configurations. An example includes 0.5-1 mm by 0.5-1 mm to form a grid array.

As such, the materials of the present disclosure can include numerous advantageous applications. For instance, in some embodiments, the materials of the present disclosure can be incorporated as interface materials of numerous electronic devices, such as processors, memory devices, graphics, power devices, micro-electromechanical systems (MEMS), sensors, flexible electronics, and/or wearable electronic devices. In some embodiments, the materials of the present disclosure can be used for double-sided cooling of electronic devices due to the optimal thermal resistance of the materials (e.g., 1 mm²-K/W).

### ADDITIONAL EMBODIMENTS

Reference will now be made to more specific embodiments of the present disclosure and experimental results that provide support for such embodiments. However, Applicants note that the disclosure below is for illustrative purposes only and is not intended to limit the scope of the claimed subject matter in any way.

### Example 1. Development of a Compliant Electrical (EIMs) and Thermal Interface Materials (TIMs) Interconnects Using Copper Nano-Wires (CuNWs)

Electronics packaging technology advancement is greatly dependent on the magnitude of interconnect stresses that ultimately limit the reliability of electronic components. Thermomechanical strains occur because of the coefficient of thermal expansion (CTE) mismatch from different conjoined materials and devices being assembled into a package. In flip chip devices, microscale solder joints are used to increase I/O density while reducing package parasitic inductance. However, the solder accommodates these CTE induced strains with their plasticity, accumulating damage that leads to creep and fatigue generated failures. Alternatively, in high temperature power packages, compatible attachment materials, such as transient liquid phase (TLP) attachment, sintered Ag, or hi-T solders, produce more rigid, fatigue cracking-susceptible connections, especially at low temperatures. Consequently, this lack of plasticity may have reduced lifetimes compared to traditional solders due to CTE induced stresses, despite allowing higher operating temperatures.

To curb the effect of thermal expansion mismatch, solder attachment based compliant interconnect structures between dies and substrates have been proposed using photolithography and additive manufacturing approaches. However, such approaches create high interconnect density, in addition to increased thermal isolation of the die from the substrate.

These structures increase the effective conduction path from the die, since they use suspended serpentine architectures to reduce the interfacial stiffness between package layers. Ideally, a compliant material, having a short conduction path could replace direct solder connections, without sacrificing density or electrical/thermal properties.

This Example describes the fabrication of novel electrically and thermally conductive interfacial structures utilizing mechanically compliant copper Nanowires (CuNWs) technology. These CuNWs can be patterned in electrically isolated arrays, matching solder joint pitch, and retain small interconnect lengths (e.g., for improved inductance and conductivity), while reducing the effective strain on the solder connection to the device. The process is projected to: (1) reduce CTE mismatch stresses on more than 15% device connections for enhanced lifetime; (2) exhibit comparable or better thermal and electrical properties to bulk solder joints; and (3) enable high temperature solders to accommodate extreme temperature delta environments.

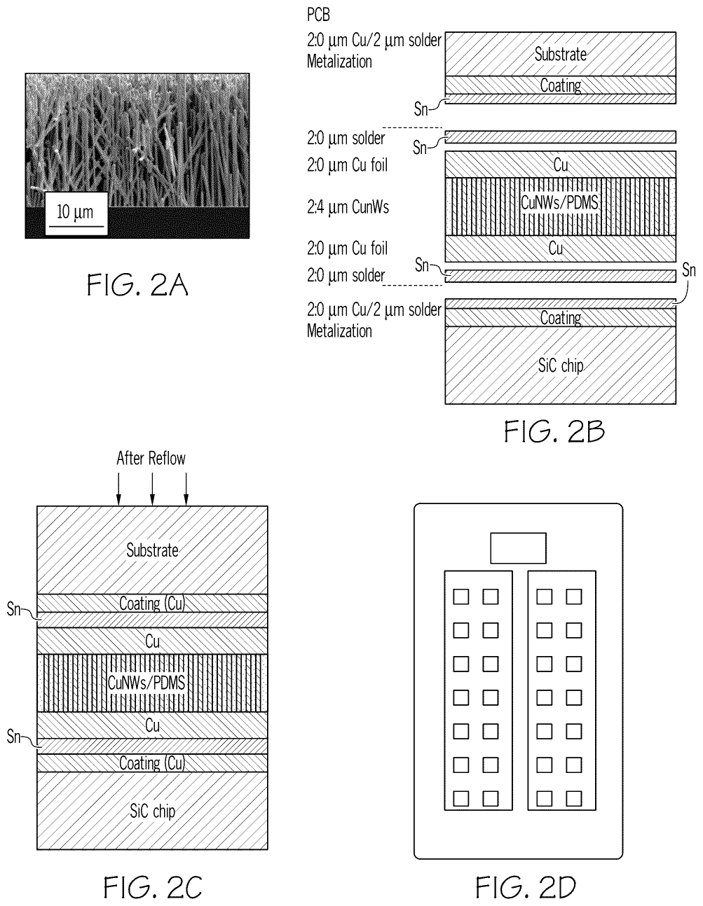

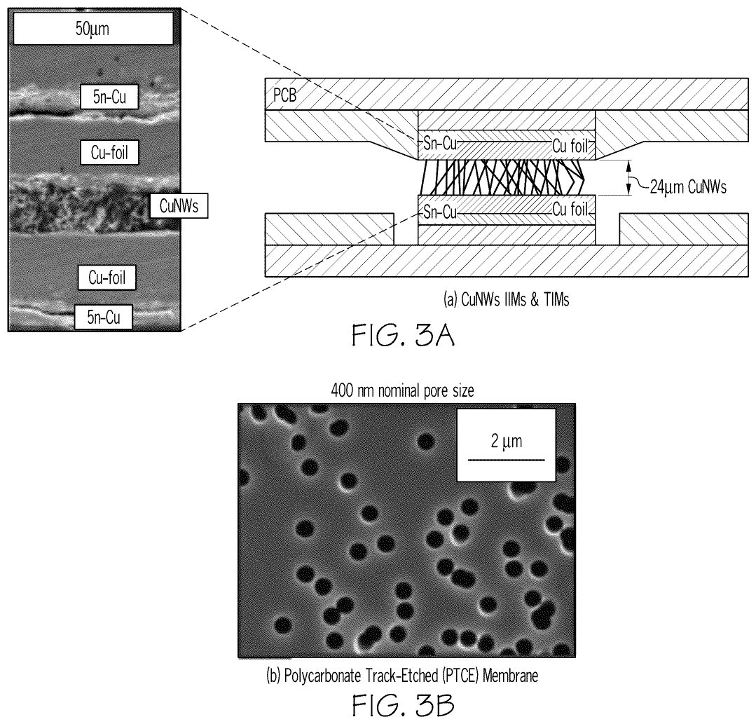

FIGS. 2A-2D and 3A-3B depict schematics of the proposed compliant electrical and thermal interface materials (EIMs & TIMs) interconnects using copper nano-wires (CuNWs) technology. The CuNW bundles can typically consist of 50-400 nm diameter wires, in groupings making a total diameter in the range of 50-100 μm for c4 interconnects, but may also include much wider arrays (mm scale) for power devices. Within the bundles, the NWs can be typically at a pitch between 3-10× the diameter of the wires, and the larger scale bundle groups can typically have a pitch 2-4× the bundle diameter. The bundles and space between them can be infiltrated with a flowable polymer (e.g., PDMS in the principal demonstration) that provides support to the NW bundles while also being thermally stable at temperatures applicable to electronics operation (e.g., it cannot degrade at temperatures around 200° C.). The targeted height of the tape can be in the 20-50 μm range to provide sufficient strain accommodation in line with typical flip-chip attachment heights. Specifically, the “EIMs & TIMs” can be fabricated in the form of a coupon that can be patterned to grid array of diameter can be 250-500 μm with ˜2× pitch.

The CuNWs offer significant advantages over solder ball grid arrays. An advantage includes higher electrical conductivity compared to Sn solder balls (e.g., substitution of a 250 μm Sn solder ball with a 30 μm tall CuNW bundle (25% fill factor) encapsulated by two of 10 μm thick Sn for bonding the CuNWs tape to the adjoining substrates). This can result in an order of magnitude reduction in electrical resistivity of the CuNWs interconnect.

Another advantage is that CuNWs-polydimethylsiloxane (PDMS) matrices are mechanically compliant. The CuNWs interconnect “tape” can be pre-patterned to any shape and form, grid array or any other configurations. Additionally, the compliant electrical and thermal interface materials (EIMs & TIMs) interconnect can enable the double-sided cooling of the power electronics chip because thermal resistance of the CuNWs TIMs tape can be in the order of 1 mm²-K/W.

### Example 1.1. Fabrication of CuNWs-PDMS Composite TIMs Tapes

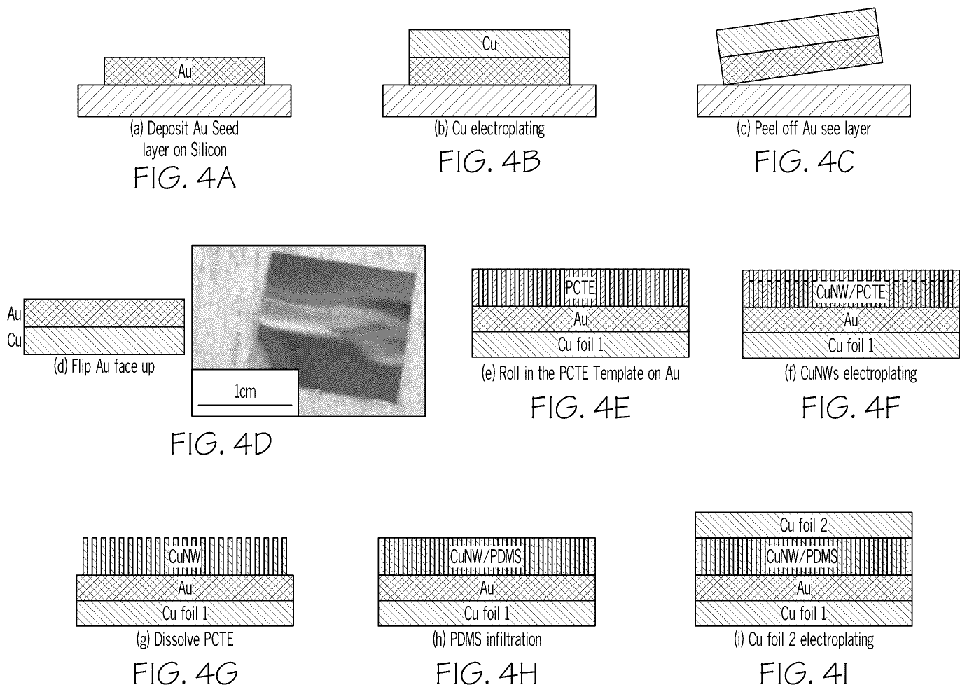

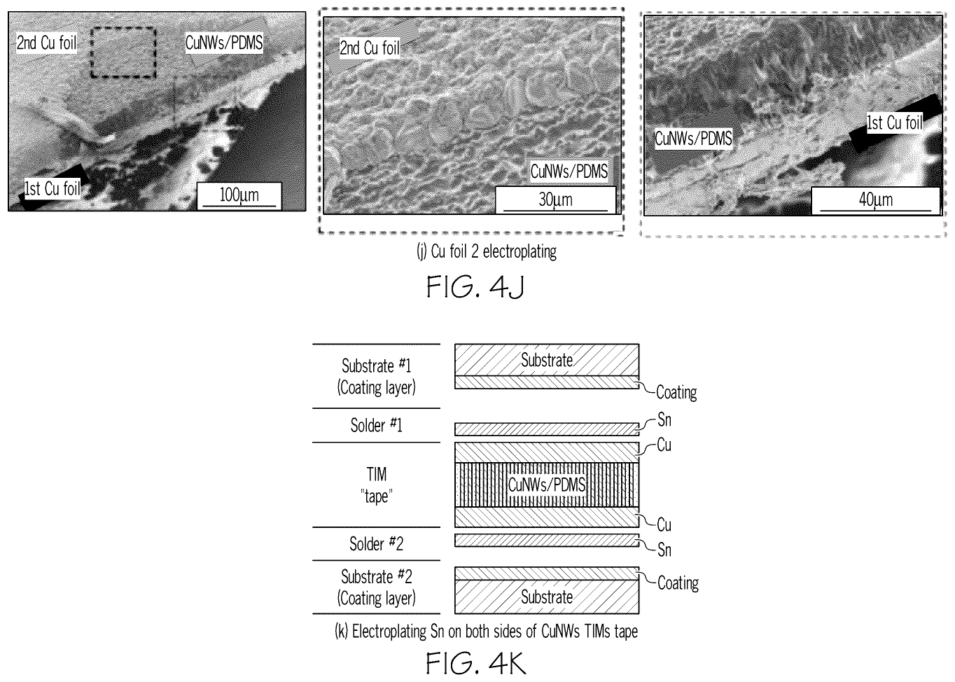

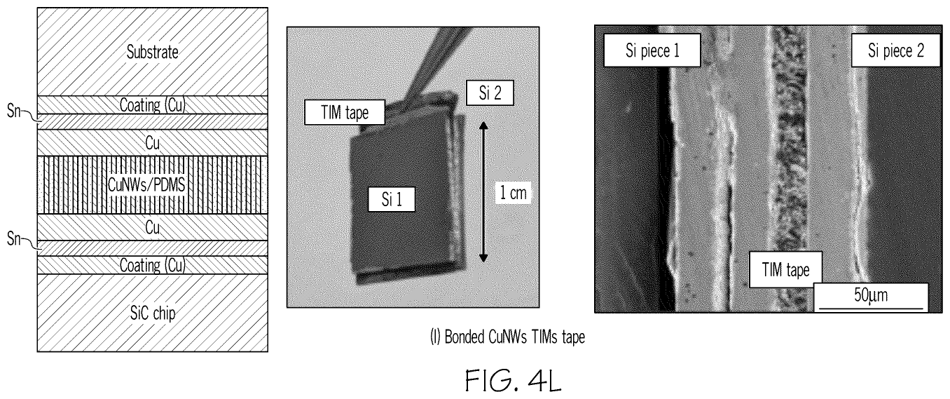

FIGS. 4A-4L provide schematics and photographs showing the synthesis of composites containing vertically aligned CuNWs-PDMS composite TIMs tape. First, an Au seed layer (weak bonding) is patterned onto a smooth silicon substrate (FIG. 4A). This is followed by electroplating 20 μm of a copper onto the Au layer (FIG. 4B), peeling off of the Au/Cu copper foil (FIG. 4C), and flipping it for the Au side to face up with a surface roughness of ˜10 nm (FIG. 4D). The polycarbonate membrane is then placed on the Au/Cu foil and rolled smooth (FIG. 4E). Next, copper is electrodeposited through the membrane pores (the NWs) and over the top of the membrane (the overplating) (FIG. 4F). Next, the overplating is peeled away to reveal the CuNW array. The membrane is then dissolved to liberate the CuNWs (FIG. 4G). Next, a polymer is placed around the perimeter, where it infiltrates the array via capillary wicking (FIG. 4H). After cross-linking the polymer, the excess material is removed, which follows additional electroplating to form Cu foli-2 (FIG. 4I).

FIG. 4J shows SEM images of composite CuNWs arrays infiltrated with TIMs tape. FIG. 4K shows the formed product with 5-10 μm of Sn on both sides of the CuNWs TIMs tape.

Such nanowires are produced in a semi-subtractive approach, which leverages both the use of a subtractive template for producing NW features through electroplating technology, followed by the use of layer-based deposition and lithographic patterning. The net result is a collection of NW bundles that are arrayed in accordance with C4 (or similar) interconnect bump pitch/size embedded in a PDMS “tape” that serves as both a carrier for the interconnect joints, as well as for providing compliance against thermomechanical strains created by CTE mismatch between device and substrate.

The nanowires used in this example were uniform pitch nanowires in the range of 50-400 nm by ˜25 μm tall, embedded in a ˜30 μm thick tape that was copper (or gold) on the surfaces, but filled with PDMS between the nanowires and Cu plated sheets on the surface. Given the success in producing broad area arrays for thermal interfaces, the key modification to make this possible is to control the growth of the nanowires in isolated regions (through masking) or alternatively, by selectively etching areas where wires are not desired (mask+etch). Subsequently, the surface of the interconnects can be patterned with electroplated Sn for direct solder attachment as an interfacial layer between the chip and substrate, so as to be able to leverage existing reflow attachment processing, or it can be augmented to incorporate high temperature attachment materials that may require alternative bonding technologies.

Without further elaboration, it is believed that one skilled in the art can, using the description herein, utilize the present disclosure to its fullest extent. The embodiments described herein are to be construed as illustrative and not as constraining the remainder of the disclosure in any way whatsoever. While the embodiments have been shown and described, many variations and modifications thereof can be made by one skilled in the art without departing from the spirit and teachings of the invention. Accordingly, the scope of protection is not limited by the description set out above, but is only limited by the claims, including all equivalents of the subject matter of the claims. The disclosures of all patents, patent applications and publications cited herein are hereby incorporated herein by reference, to the extent that they provide procedural or other details consistent with and supplementary to those set forth herein

1. A material comprising:
a first copper-based layer;
a copper nanowire layer above the first copper-based layer, wherein the copper nanowire layer comprises a plurality of copper nanowires embedded with a polymer; and
a second copper-based layer, wherein the second copper-based layer is positioned above the copper nanowire layer such that the copper nanowire layer is sandwiched between the first copper-based layer and the second copper-based layer.

2. The material of claim 1, wherein the first copper-based layer comprises a first copper layer, a second copper layer, and a Sn layer sandwiched between the first copper layer and the second copper layer, wherein the second copper layer interfaces with the copper nanowire layer.

3. The material of claim 1, wherein the second copper-based layer comprises a first copper layer, a second copper layer, and a Sn layer sandwiched between the first copper layer and the second copper layer, wherein the first copper layer interfaces with the copper nanowire layer.

4. The material of claim 1, wherein the plurality of copper nanowires are in the form of an array of vertically aligned nanowires.

5. The material of claim 1, wherein the plurality of copper nanowires are infiltrated with the polymer.

6. The material of claim 1, wherein the polymer comprises an elastomeric polymer.

7. The material of claim 1, wherein the polymer comprises polydimethylsiloxane (PDMS).

8. The material of claim 1, further comprising a first substrate beneath the first copper-based layer.

9. The material of claim 1, further comprising a second substrate above the second copper-based layer.

10. The material of claim 1, wherein the material is a thermal interface material that is electrically and thermally conductive.

11. The material of claim 1, wherein the material is a component of an electronic device.

12. The material of claim 11, wherein the material is positioned on the electronic device in the form of an array, wherein the array comprises a plurality of materials.

13. The material of claim 12, wherein the plurality of materials are electrically isolated from one another.

14. The material of claim 11, wherein the electronic device is selected from the group consisting of processors, memory devices, graphics, power devices, micro-electromechanical systems (MEMS), sensors, flexible electronics, wearable electronic devices, or combinations thereof.

15. A method of forming a material, said method comprising:
growing a copper nanowire layer on a first copper-based layer;
embedding the copper nanowire layer with a polymer; and
positioning a second copper-based layer above the copper nanowire layer such that the copper nanowire layer becomes sandwiched between the first copper-based layer and the second copper-based layer.

16. The method of claim 15, further comprising a step of positioning a first substrate beneath the first copper-based layer.

17. The method of claim 15, further comprising a step of positioning a second substrate above the second copper-based layer.

18. The method of claim 15, wherein the first copper-based layer comprises a first copper layer, a second copper layer, and a Sn layer sandwiched between the first copper layer and second copper layer, wherein the second copper layer interfaces with the copper nanowire layer.

19. The method of claim 15, wherein the second copper-based layer comprises a first copper layer, a second copper layer, and a Sn layer sandwiched between the first copper layer and the second copper layer, wherein the first copper layer interfaces with the copper nanowire layer.

20. The method of claim 15, wherein the plurality of copper nanowires are in the form of an array of vertically aligned nanowires.

21. The method of claim 15, further comprising a step of incorporating the material as a component of an electronic device.

22. The method of claim 21, wherein the incorporating comprises positioning the material on the electronic device in the form of an array, wherein the array comprises a plurality of materials.

23. The method of claim 22, wherein the plurality of materials are electrically isolated from one another.

24. The method of claim 21, wherein the electronic device is selected from the group consisting of processors, memory devices, graphics, power devices, micro-electromechanical systems (MEMS), sensors, flexible electronics, wearable electronic devices, or combinations thereof.
